(19) United States
(12) Patent Application Publication
(10) Pub. No.: US 2011/0175074 A1
(43) Pub. Date: Jul. 21, 2011

(54) COMPONENTS AND CIRCUIT ARRANGEMENTS INCLUDING AT LEAST ONE ORGANIC FIELD-EFFECT TRANSISTOR

(75) Inventors: Ronald Osterbacka, Abo (FI); Carl-Erik Wilen, Esbo (FI); Nikolai Kaihovirta, Abo (FI); Carl-Johan Wikman, Abo (FI); Tapio Mäkelä, Helsinki (FI)

(73) Assignees: Ronald Osterbacka, Abo (FI); Carl-Erik Wilen, Esbo (FI)

(21) Appl. No.: 13/055,248

(22) PCT Filed: Jul. 20, 2009
(86) PCT No.: PCT/FI2009/050635

§ 371 Date: Mar. 3, 2011

(30) Foreign Application Priority Data
Jul. 21, 2008 (FI) 20085737

(51) Int. Cl. H01L 51/52

(52) U.S. Cl. 257/40; 257/E51.018

(57) ABSTRACT

A circuit arrangement comprises a first electronic component, which is an organic field-effect transistor. It comprises a source electrode (111), a drain electrode (112), a channel region (113) and a gate electrode (114). A second electronic component is electrically coupled to the first electronic component. A membrane (101) exhibits ion-conductivity between the channel region (113) and the gate electrode (114). The membrane also exhibits ion-conductivity in a section (121) of the membrane that is located between a first part of the second electronic component and a second part of the second electronic component.

### FIELD OF THE INVENTION

The invention concerns generally components and circuit arrangements that include at least one organic field-effect transistor. Especially the invention takes advantage of appropriate selection of materials, configurations and manufacturing methods to achieve advantageous synergies by combining organic field effect transistors with other components using a common membrane as a substrate.

### BACKGROUND OF THE INVENTION

The basic technology of organic field-effect transistors (OFET) is well known and established. A previously filed patent application number PCT/FI2008/000015, which at the date of writing this specification belongs to the same applicants and is not yet available to the public, provides an extensive explanation of basic concepts in this technical field. Said previous patent application also introduces the novel concept of forming an electric double layer capacitance (EDLC) by ensuring ion-conductivity in a membrane located between the channel region and the gate electrode in the OFET. Said previous patent application is incorporated herein by reference.

From the technology of integrated circuits it is well known as such to use a common substrate, upon which a circuit arrangement is constructed by locally modifying the electric properties of the substrate and by adding carefully designed pattern layers. Similar principles have been adopted in organic semiconductor technology, with the specific feature that the substrate is frequently a flexible thin film. However, if the required number of layers is large, if alignment between layers must be very accurate, and/or if the manufacturing process becomes complicated for other reasons, the structure works against some basic advantages of organic semiconductor technology, which include (but are not limited to) low manufacturing costs, suitability for manufacturing in printing machines, and the relative ease of combining OFET-based electronics with different technologies like package manufacturing and printed media.

### BRIEF DESCRIPTION OF THE INVENTION

An objective of the present invention is to provide components and circuit arrangements in which organic field-effect transistors are combined with other circuit elements in a simple, effective and advantageous manner. Another objective of the invention is to provide components and circuit arrangements of said kind, in which only low operating voltages are needed. Yet another objective of the invention is to provide components and circuit arrangements of said kind, which are easily applicable to large-scale mass manufacturing. Yet another objective of the invention is to provide components and circuit arrangements of said kind, which can be made self-supportive using the integrated structural layers of at least some of the components.

The objectives of the invention are achieved by utilizing local ion-conductivity of a membrane to facilitate the electric operation of both an organic field-effect transistor and another electronic component coupled to the organic field-effect transistor.

According to a first aspect of the present invention a circuit arrangement comprises a first electronic component (which is an organic field-effect transistor and comprises a source electrode, a drain electrode, a channel region and a gate electrode), a second electronic component (which is electrically coupled to said first electronic component), and a membrane that is capable of constituting a mechanical support of the organic field-effect transistor. The circuit arrangement is characterized in that
the membrane exhibits ion-conductivity between the channel region and the gate electrode, and
the membrane exhibits ion-conductivity in a section of the membrane that is located between a first part of the second electronic component and a second part of the second electronic component.

According to a second aspect of the present invention a display unit comprises:
a first electronic component, which is an organic field-effect transistor and comprises a source electrode, a drain electrode, a channel region and a gate electrode,
a membrane, which exhibits ion-conductivity between the channel region and the gate electrode and is capable of constituting a mechanical support of the organic field-effect transistor, and
a layer of electrophoretic material located adjacent to at least one of said source electrode and said drain electrode.

The characteristic of (local) ion-conductivity in a membrane has been found to constitute a practical means for administering electric conductivity to locations where it is needed, while simultaneous preserving other advantageous characteristics of the membrane, like mechanical strength and isolation against cross-talk.

In this description we consider combining organic field-effect transistors, the operation of which is based on ion-conductivity of the membrane between the gate electrode and the channel region, with other components to form circuit arrangements. Also said other components may take advantage of suitably created (or, in some cases, even suitably destroyed or modified) ion-conductivity of the same membrane. The circuit arrangement thus created has many advantageous features. Alignment between different patterns is not critical, because the effects generated through the ion-conductivity of the membrane are typically not heavily dependent on small changes in physical dimensions. The thickness of the membrane can be in the order of tens or even hundreds of micrometres without seriously deteriorating the electric operability of those components that rely on ion-conductivity in the membrane. Thus the membrane can be sufficiently thick to act as a mechanical support, at least during roll-to-roll handling in manufacturing stages but in some cases even in completed products. Utilizing the membrane as one of the layers that take part in the electric operation of the components reduces the number of additionally required layers and patterns, which simplifies the structure and helps to streamline manufacturing processes. Substantially complete circuit arrangements can be produced in a process that is essentially a printing process.

The exemplary embodiments of the invention presented in this patent application are not to be interpreted to pose limitations to the applicability of the appended claims. The verb “to comprise” is used in this patent application as an open limitation that does not exclude the existence of also unrecited features. The features recited in depending claims are mutually freely combinable unless otherwise explicitly stated.

The novel features which are considered as characteristic of the invention are set forth in particular in the appended claims. The invention itself, however, both as to its construction and its method of operation, together with additional objects and advantages thereof, will be best understood from the following description of specific embodiments when read in connection with the accompanying drawings.

### BRIEF DESCRIPTION OF DRAWINGS

FIG. 1 illustrates a general principle of combining a MEM-FET with another component.

### DETAILED DESCRIPTION OF EMBODIMENTS OF THE INVENTION

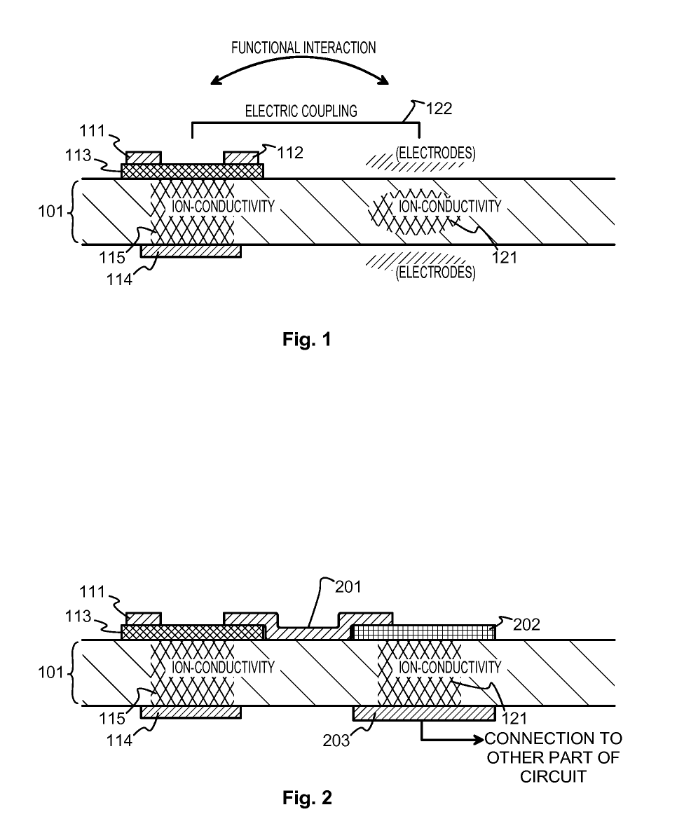

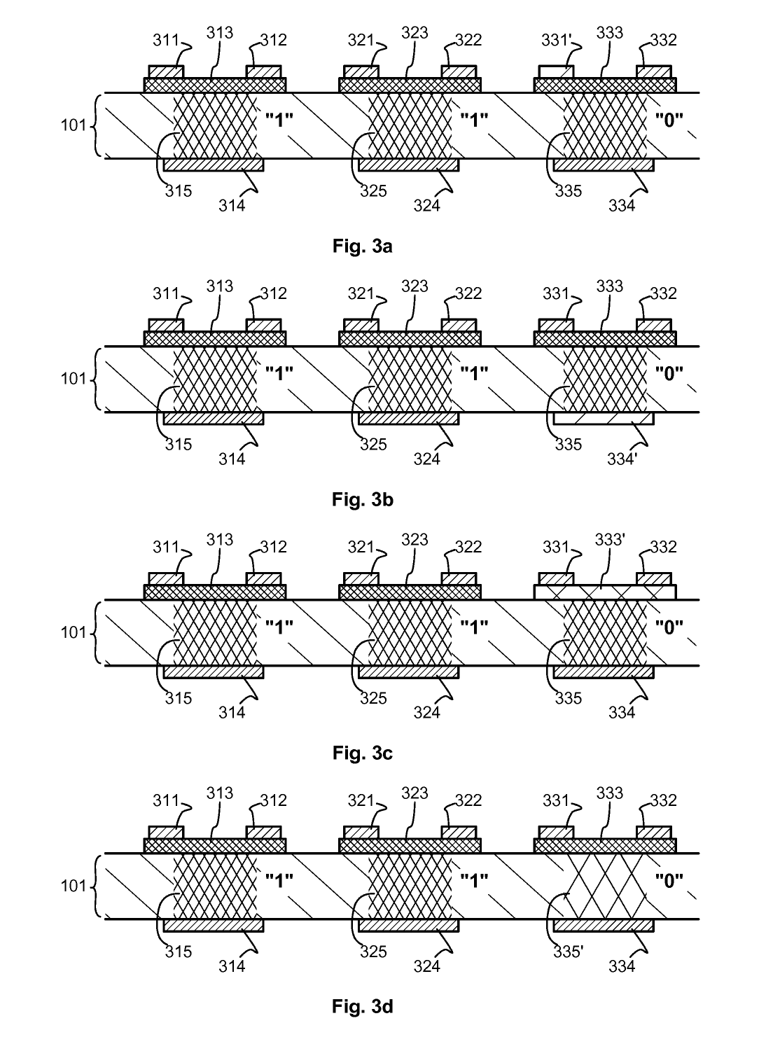

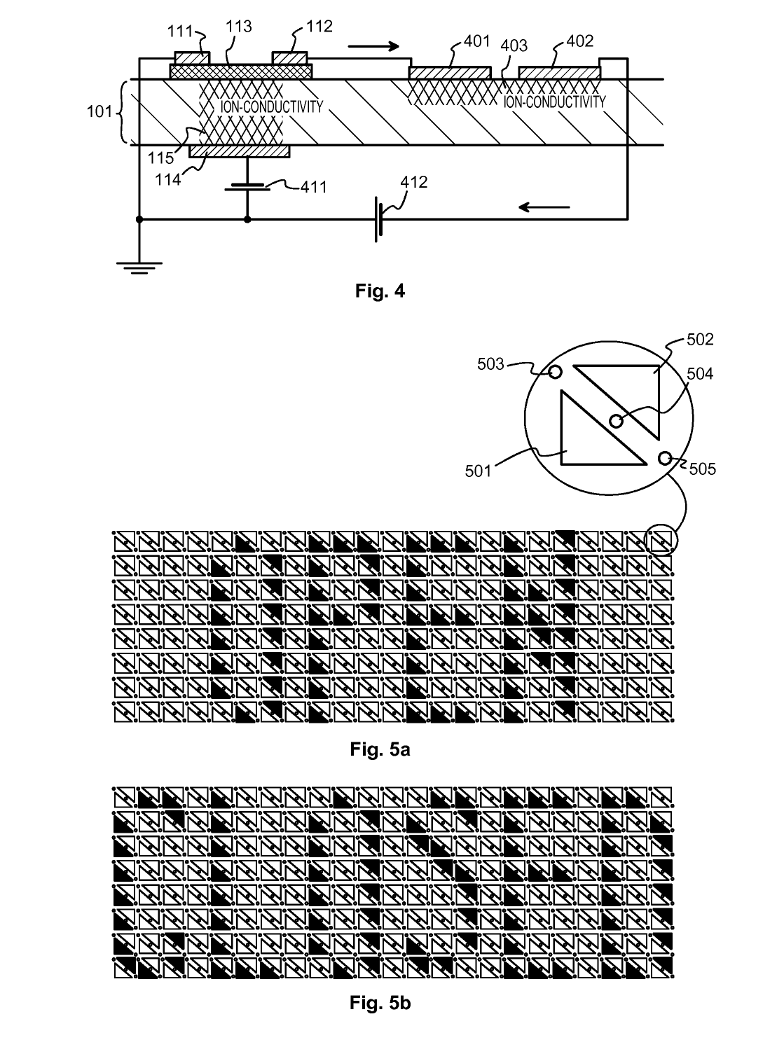

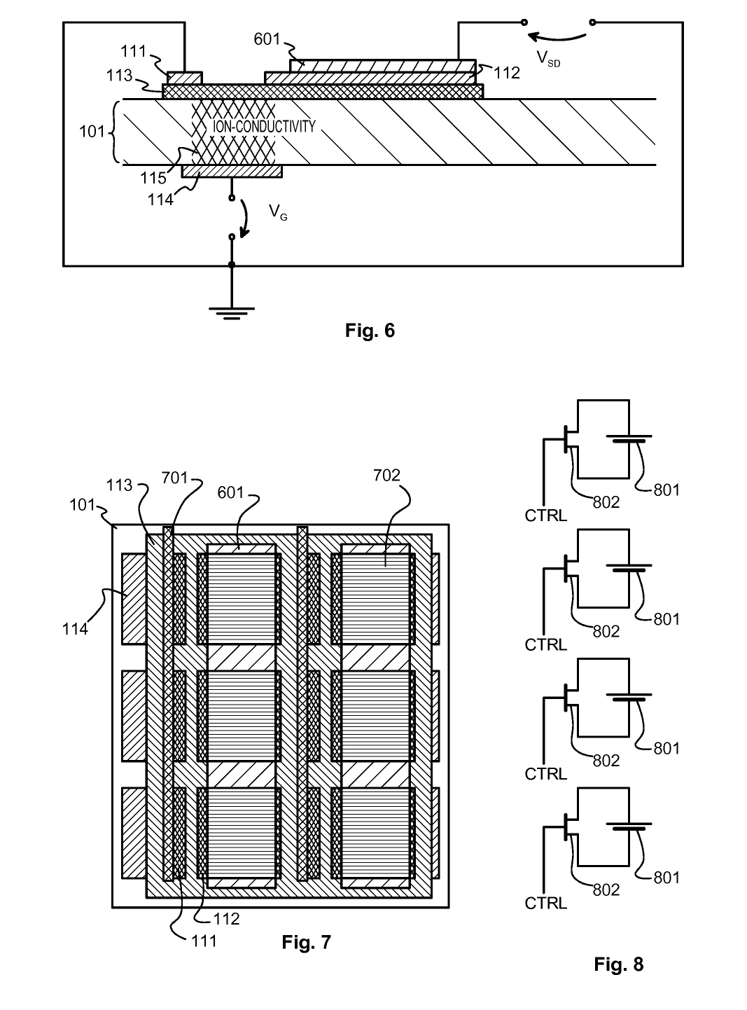

FIG. 1 is a cross-section that illustrates a principle of combining two electronic components, both of which are built using a membrane 101. On the left in the drawing is the first electronic component, which is an organic field-effect transistor. It comprises a source electrode 111, a drain electrode 112, a channel region 113, and a gate electrode 114. The channel region 113 occupies a part of one surface of the membrane 101. The source electrode 111 and the drain electrode 112 are both in contact with the channel region 113; in other words the channel region 113 connects the source electrode 111 and the drain electrode 112 to each other. Such a condition can be achieved with a wide variety of geometries. In this simple example the channel region 113 is a patch or strip of a polymeric semiconductor like RR-P3HT (regioregular poly(3-hexylthiophene)) or the like on one surface of the membrane 101, and the source and drain electrodes 111 and 112 are patches or strips of a conductive polymer, metal, or other substance, the electric conductivity of which is much better than that of the polymeric semiconductor. The gate electrode 114 is similarly a patch or strip of a conductive polymer, metal, or other substance, the electric conductivity of which is much better than that of the polymeric semiconductor used for the channel region 113. The gate electrode is located on the opposite surface of the membrane, and at least partly coincides with the area that the channel region 113 covers on the other side of the membrane 101.

The mechanical structure of the organic FET can be (but is not necessarily) completely symmetrical with respect to which of the top electrodes is source and which is drain. Therefore the selection of source 111 on the left and drain 112 on the right in FIG. 1 should be considered as an example only.

In general the materials used for the organic FET are not essential to the present invention. For example, all regioregular poly(alkyl-thiophene)s are believed to be suitable for the organic semiconductor layer that constitutes the channel region. A commonly used substance for conductive electrodes is PEDOT:PSS (poly(2,3-dihydrothieno-[3,4-b]-1,4-dioxin) and poly(styrenesulfonate)), which is a conductive polymer. Depending on the applied naming standard, PEDOT is also known as poly(dihydrothienodioxine) or polyethylenedioxythiophene. Using PEDOT together with PSS makes it useful as an electric conductor regardless of small changes in the redox state of the material that may arise from electrochemical processes. Also various blends of PANI (polyaniline) are frequently used as conductive polymers. It should noted that the embodiments of the invention are not limited into these specific examples described above. These are merely described as illustrative examples.

An important factor of the operation of the organic field-effect transistor of FIG. 1 is that the membrane 101 exhibits ion-conductivity between the channel region 113 and the gate electrode 114. The spatial section of ion-conductivity is illustrated as with reference number 115. When a gate potential (not shown) is connected to the gate electrode 114, the ion-conductivity of region 115 gives rise to an electric double layer capacitance (EDLC) effect, resulting in significant changes in the conductivity of the channel region 113. This particular principle of realising an organic field-effect transistor (OFET) has been described in detail in the previously filed patent application number PCT/FI2008/000015 mentioned earlier. It is believed that the designation membrane-FET or MEM-FET will become common to designate an OFET where the ion-conductivity of the membrane plays a significant role.

According to the general principle illustrated in FIG. 1, there is a second electronic component, which is electrically coupled to the first electronic component (the OFET, or MEM-FET like it is here also called). The second electronic component is also built utilizing the membrane 101. FIG. 1 does not take any more detailed position concerning the structure of the second electronic component, otherwise than expecting that the membrane 101 exhibits ion-conductivity in a section 121 of the membrane 101 that is located between a first part of the second electronic component and a second part of the second electronic component. Said first and second parts may be comprise electrodes on one or both sides of the membrane (hence the designations “electrodes” in parentheses in FIG. 1). The electric coupling 122 between the MEM-FET and the second electronic component is shown quite schematically in FIG. 1. As a result of the electric coupling 122 there is some functional interaction between the MEM-FET and the second electronic component. Typically the functional interaction is such that changes in the conductivity of the channel region 113 cause changes in electric currents and/or potentials that also affect the state of the second electronic component, in turn causing phenomena that involve the mobility of charge carriers in the ion-conductive section 121. The cause and effect may be also the other way round, so that the mobility of charge carriers in the ion-conductive section 121 gives rise to a phenomenon that affects the currents and/or potentials in various parts of the MEM-FET.

As a first example we consider a circuit arrangement in which the second electronic component is an electrochemical power source, more specifically a zinc-air battery. It comprises an anode and a cathode, and the membrane exhibits ion-conductivity in a section of the membrane that is located between said anode and said cathode. Thus the ion-conductive section of the membrane constitutes a solid electrolyte that is essential for the operation of the zinc-air battery.

In FIG. 2 the MEM-FET on the left is similar to that described above with reference to FIG. 1, with the exception that the electrode which was above designated as the drain is shown to continue as a bridge-like conductive structure 201 towards and up to the anode 202 of a zinc-air battery. The cathode 203 of the zinc-air battery is located on the other side of the membrane 101, and the section 121 of ion-conductivity in the membrane extends transversally across the membrane through the whole thickness of the membrane between said anode and cathode of the zinc-air battery. The anode 202 comprises zinc, and the cathode 203 is some conductive layer which allows the normal cathode reaction O₂+2H₂O+4e⁻→4OH⁻ of a zinc-air battery to take place. In a laboratory measurement the anode was a layer of metallic zinc, and a cathode was constructed by soaking a piece of a paper towel in slurry of carbon powder in ethanol. A voltage meter gave 0.8 V as the output voltage of such an electrochemical power source.

The zinc-air battery is given here as an example only. The invention allows also other kinds of electrochemical power sources to be built according to a similar principle: an anode layer is at one point of the membrane, a cathode layer is at another point of the membrane, an ion-conductive section of the membrane between the anode and cathode layers constitutes the electrolyte, and the anode and cathode materials have been selected according to their electrochemical properties so that the overall chemical reaction in the system consisting of the anode, cathode, and electrolyte gives rise to an electric potential difference between the anode and cathode. Examples of electrochemical power sources include but are not limited to galvanic cells, electrolytic cells, fuel cells, flow cells, and voltaic piles. Just like in the case of more conventional electric power sources, serial and parallel connections of the membrane-based electrochemical power sources can be used to achieve the desired output voltage, current feeding capacity, and other electric properties.

Also the electrically conductive connection between the drain of the MEM-FET and the anode of the zinc-air battery is given here as an illustrative example only. An electrochemical power source of the kind outlined above is a generic source of electric energy and can be used and connected in electronic circuitry in a wide variety of ways. The ease of setting up electrochemical power sources by preparing a suitable section of ion-conductivity in the membrane and producing the appropriate anode and cathode patterns in connection with said section of ion-conductivity means that circuit designers are not limited to conducting electric energy from some distant, centralized source powering the circuit. Local, spot-like energy sources can be distributed all around the circuit at all locations where they are needed.

In principle it is not necessary to have the anode and cathode of an electrochemical power source on different sides of the membrane. An alternative structure could be presented, in which the cathode is located on the same side of the membrane as the anode, and the membrane exhibits ion-conductivity in a section of the membrane that extends longitudinally along the membrane through at least a part of the distance between the anode and cathode.

As a next example we consider a circuit arrangement in which the second electronic component is an organic field-effect transistor, but at least one part of which has been made non-functional, in order to make the second electronic component a memory cell with a fixed value. We could characterize the resulting memory circuit as a Write Once Read Many times (WORM) memory: during a write pass, those MEM-FETs that should represent a first logical value (say, 1) are left intact, while those MEM-FETs that should represent a second logical value (say, 0) are deliberately made non-functional by damaging some part of the MEM-FET so that it does not function normally. Afterwards the logical value written in the memory can be read many times, but at least the second logical values (the 0s) are fixed in the sense that they cannot be returned to “1”, because the damaged property of the corresponding MEM-FET cannot be repaired.

FIGS. 3a, 3b, 3c, and 3d each illustrate a cross section of a memory circuit which has undergone a write pass to write a bit pattern “110” to memory. Consequently in each of FIGS. 3a, 3b, 3c, and 3d the left and middle MEM-FETs are in original condition but the rightmost MEM-FET has been deliberately damaged to make it represent a different logical value than the others. The same reference designators are used in each of FIGS. 3a, 3b, 3c, and 3d: 311, 321, and 331 for the source electrode; 312, 322, and 332 for the drain electrode; 313, 323, and 333 for the channel region; 314, 324, and 334 for the gate electrode; as well as 315, 325, and 335 for the ion-conductive section of the membrane that facilitates the operation of the MEM-FET in question.

In FIG. 3a the source electrode of the rightmost MEM-FET has been deliberately damaged; hence the dotted notation 331′. As a result, the source electrode 331′ is not as conductive as the normal, undamaged source electrodes 311 and 321 of the other MEM-FETs. The memory circuit could have e.g. the source electrode of each MEM-FET coupled to a constant non-zero potential and the drain electrode of each MEM-FET coupled through a pull-up resistor to ground. A readout circuit (not shown) could be configured to selectively couple the gate electrode of each MEM-FET to a potential that under normal conditions is sufficient to open a current path through the channel region, and to read the resulting potential of the drain electrode. In the left and middle MEM-FETs the potential of the drain electrode would be essentially equal to said constant non-zero potential minus the voltage drop over the source-drain junction of a MEM-FET. In the rightmost MEM-FET of FIG. 3a the lower conductivity of the source electrode 331′ would cause the drain potential to be much lower.

Previously we have already pointed out that the structure of the MEM-FET can (but does not have to) be symmetrical regarding source and drain. Concerning FIG. 3a we may say that at least one of the source and drain electrodes of the rightmost MEM-FET has been deliberately damaged (or more generally: its conductive properties have been deliberately modified) to make the MEM-FET respond differently to a gate voltage than the other, non-modified MEM-FETs.

FIG. 3b illustrates a functionally similar situation, however so that the gate electrode of the rightmost MEM-FET has been deliberately damaged; hence the dotted notation 334′. As a result, the gate electrode 334′ is not as conductive as the normal, undamaged gate electrodes 314 and 324 of the other MEM-FETs. The functional effect is the same as above: if a readout circuit (not shown) tried to set the rightmost MEM-FET into conductive state by applying a gate voltage, the lowered conductivity of the gate electrode 334′ would keep the source-drain junction of the rightmost MEM-FET from becoming as conductive as the source-drain junctions of the other MEM-FETs, which would have the obvious consequence of generating a different readout voltage regardless of the actual structure and configuration of the readout circuit.

FIG. 3c illustrates another functionally similar situation, however so that the channel region of the rightmost MEM-FET has been deliberately damaged; hence the dotted notation 333′. As a result, a gate voltage coupled to the rightmost MEM-FET would not increase the number of free charge carriers in the channel region 333′ as much as in the normal, undamaged channel regions 313 and 323 of the other MEM-FETs. The functional effect is again the same as above: if a readout circuit (not shown) tried to set the rightmost MEM-FET into conductive state by applying a gate voltage, the impaired ability of becoming more conductive of the channel region 333′ would keep the source-drain junction of the rightmost MEM-FET from becoming as conductive as the source-drain junctions of the other MEM-FETs, which would have the obvious consequence of generating a different readout voltage regardless of the actual structure and configuration of the readout circuit.

FIG. 3d illustrates yet another functionally similar situation. From the viewpoint of verbal description this case differs slightly from the circuit arrangement above, because it is now the lowered ion-conductivity of the membrane that makes the rightmost MEM-FET non-functional. Thus, if we describe an aspect of the invention so that the membrane exhibits ion-conductivity between the channel region and the gate electrode of an organic field-effect transistor (the one on the left) and the membrane also exhibits ion-conductivity (of a similar magnitude) in a section of the membrane that is located between first and second parts of the second electronic component, we must actually designate the middle MEM-FET as the second electronic component. In addition to the first and second electronic components (which are both fully functional MEM-FETs) the circuit arrangement of FIG. 3d comprises a third electronic component, which is a non-functional organic field effect transistor and comprises a source electrode 331, a drain electrode 332, a channel region 333, and a gate electrode 334. The ion-conductivity in a section 335′ of the membrane that is located between the channel region 333 and the gate electrode 334 of the third electronic component is lower than the ion-conductivity that the membrane exhibits between the channel region and the gate electrode of the first (and second) electronic component(s), in order to make the third electronic component a memory cell with a fixed value.

It is not important to the present invention, what mechanism is utilized to make a MEM-FET deliberately non-functional. If the non-functionality is due to a lowered electric conductivity of a part of the MEM-FET that is made of a conductive or semiconductive polymer, a practical way of achieving the desired decrease in conductivity is to “burn”, i.e. overoxidize or overreduce, the polymer by applying a discharge of electric energy through at a level that is high enough to permanently modify the characteristics of the polymer. In practice this means applying a high enough voltage and/or current between at least two of the source, drain, and gate electrodes. It is not necessary to aim at overoxidizing or overreducing exactly one part of a MEM-FET and leaving other parts as they are; indeed it is common that applying a damaging discharge of electric energy through a MEM-FET will cause changes in the electric conduction properties of more than one part of the MEM-FET. Other ways of altering the functionality of a MEM-FET can be used as well, like focusing laser, ultraviolet or other electromagnetic radiation, or an electron beam or ion beam, carefully to desired parts of an array of MEM-FETs.

If the functionality/non-functionality of MEM-FETs is based on the condition of the ion-conductive section of the membrane, it is even possible to present an embodiment of the invention in which the membrane does not comprise ion-conductive sections in the beginning, but only “blank” MEM-FETs with the electrodes and channel regions. The ion-conductive sections are formed only as the write pass step of manufacturing a WORM memory: for example an electron beam is focused onto that part of the membrane that comprises the electrodes and channel region of a MEM-FET that should be made functional, followed by the suitable chemical treatment steps that finalize the local creation of ion-conductivity. Such a method is a kind of reverse from what was described above by stating that some of the previously completed functional MEM-FETs should be made non-functional by locally destroying the ion-conductivity. The end result is the same in any case: in an array of MEM-FETs some are functional, each representing a first logical value, while some others are not functional, each of them representing a second logical value.

As a next example we consider a circuit arrangement in which the second electronic component is an electrochromic display unit. The technology of electrochromic displays is well known from for example the publication Peter Andersson, Robert Forchheimer, Payman Tehrani and Magnus Berggren: “Printable All-Organic Electrochromic Active-Matrix Displays”, Advanced Functional Materials, vol. 17, no. 16, pp. 3074-3082 (2007). An organic electrochromic display unit comprises a so-called redox-active electrochromic polymer, which has the characteristic that oxidation or reduction (or both) causes significant change in the absorption of visible light in the polymer. Reversible oxidation and reduction can be achieved by changing the amount and direction of electric current through the redox-active electrochromic polymer. A simple electrochromic display unit comprises one or a few patches made of polyaniline, viologen, or polyoxotungstate, as well as the electric connections that are used to supply the bursts of electric charge that are needed to change the absorption state of the electrochromic material.

FIG. 4 illustrates a circuit arrangement which comprises a MEM-FET on the left and a simple, two-patch electrochromic display unit on the right. The drawing also illustrates schematically an exemplary principle of connecting voltages between different parts of the circuit arrangement. The MEM-FET is similar to that described above in association with FIG. 1. From the drain electrode 112 there is an electrically conductive connection to a first electrode 401 of the electro-chromic display unit. Between the first 401 and second electrode 402 of the electrochromic display unit there is an electrolytic coupling through an ion-conductive section 403 of the membrane. In this case the first and second parts of the electrochromic display unit are thus located on the same side of the membrane, and the ion-conductive section extends longitudinally along the membrane through at least a part of the distance between said first and second parts (the first and second electrode) of the second electronic component (the display unit). We assume that the first 401 and second 402 electrodes of the electrochromic display unit are made of, or at least comprise a substantial amount of, a redox-active electrochromic polymer like polyaniline.

FIG. 4 illustrates an exemplary way of making electric connections between the MEM-FET, the display unit and certain voltages. The source electrode 111 is here coupled to a fixed (ground) potential. Between the source electrode 111 and the gate electrode 114 a voltage source 411 creates a gate voltage for the MEM-FET. Another voltage source 412 is coupled between said fixed potential and the second electrode 402 of the electrochromic display unit. The polarities of said voltage sources 411 are such that an electric current flows from the drain electrode 112 into the first electrode 401 of the electrochromic display unit, and out of the second electrode 402 of the electrochromic display unit to the negative pole of the second voltage source 412. In the ion-conductive section 403 the flow of electric current is due to the migration of ions, which means that the redox-active electrochromic polymer of one of the electrodes is oxidized while the other is reduced changing the colour of the electrochromic polymer. Taken the directions of electric current in FIG. 4, the electrode to become darker is the first electrode 401. It should be also noted that it's possible one of the electrodes may become darker. If the polarity of the second voltage source 412 was flipped over, the electric current through the display unit would change its direction, the roles of the electrodes in the display unit would be reversed, and the first electrode 401 would become darker than the second electrode 402.

Using two symmetrically reacting electrodes in the display unit means thus that, depending on the direction of the electric current, a selected one of the electrodes becomes darker. If no electric current flows through the display unit, both electrodes may appear almost transparent, or at least significantly lighter in colour than the dark colour caused by the reduction reaction. It is also possible to produce an alternative display unit in which only one of the electrodes contains a redox-active electrochromic polymer. In such a case the display unit is a simple, monochromatic (=“black and white”) display unit that produces a darker or lighter picture element depending on whether the current through the display unit is switched on or off. Terms like black and white should be taken figuratively, because the “white” colour of the display unit will correspond to the natural colour of an electrode containing redox-active electrochromic polymer without temporary reduction caused by electric current, while the “black” colour will correspond to the colour of the electrode containing redox-active electrochromic polymer with temporary reduction caused by electric current.

FIGS. 5a and 5b illustrate schematically an exemplary way of constructing a larger display, the picture elements or pixels of which are implemented using the technology illustrated in FIGS. 2 and 4. Each display unit in the display comprises two adjacent, triangular pixels 501 and 502 as illustrated in the partial enlargement at the top right of FIG. 5. Each triangular pixel is thus an electrode of an electrochromic display unit of the kind illustrated in FIG. 4. Additionally each display unit in the display comprises at least one MEM-FET 503 used as a switch, as well as one or more electrochemical power sources 504 and 505. The electric connections between the parts of the display unit, as well as the connection lines needed to selectively give switching commands to each display unit from a display controller (not shown), are not illustrated for reasons of graphical clarity. FIGS. 5a and 5b show the same display, with a first subset of pixels activated in FIG. 5a and a second subset of pixels activated in FIG. 5b.

Different grades of redox-active electrochromic polymers can be made to generate different colours. Additionally the colour(s) that a human viewer perceives can be affected with suitable use of lighting, like e.g. a uniform or patterned background lighting. A polychromatic (=multi-colour) display can be produced by manufacturing groups of adjacent pixels with different compositions of redox-active electrochromic polymers in each pixel, and arranging the individual addressing of pixels so that desired combinations of colours can be selectively produced.

The well-known applicability of conductive (and also redoxactive electrochromic) polymers to print-like manufacturing makes it especially easy to pattern the surface of a display with “pixels” or picture elements of almost any size and shape. The possibility of using distributed electrochemical power sources along the membrane near those places where electricity is consumed helps to avoid losses that could otherwise exist if electric energy should be brought from some centralized electric power source through long conductive connections.

FIG. 6 illustrates another way of utilizing MEM-FET technology for making a display unit. The cross-section of FIG. 6 illustrates a simple, one-element display unit, where a central electronic component is an organic field-effect transistor. It comprises a source electrode 111, a drain electrode 112, a channel region 113 and a gate electrode 114. In conformity with the MEM-FETs described earlier in this text, there is a membrane 101, which exhibits ion-conductivity between the channel region 113 and the gate electrode 114. The part of the display unit to produce the actual visual effects needed for operation as a display is a layer of electrophoretic material 601 located adjacent the drain electrode 112. As such, it could also be located adjacent to the source electrode 111, or electrophoretic material could be used adjacent to both the source electrode 111 and the drain electrode 112.

Electrophoresis in general refers to the well-known tendency of particles dispersed in a fluid to migrate under influence of an applied electric field. An electrophoretic display is a display that forms visible images by rearranging charged pigment particles (or charged particles acting as vehicles for moving pigment in some form) using an electric field. A large number of known electrophoretic materials exist, usually referred to as e-inks, e-papers or the like because they can be used to mimic the visual appearance of paper patterned with ink. For the purposes of the present invention it is not important, what specific brand or type of electrophoretic material is used.

Making the layer of electrophoretic material 601 in the display unit of FIG. 6 appear as having a specific colour requires passing an electric current through the MEM-FET, so that an electric surface charge on the surface of that electrode that is adjacent to the electrophoretic material 601 produces a sufficiently strong electric field to affect the spatial distribution of the pigment carriers. As an example we may assume that the electrophoretic material is capable of selectively displaying either a white colour or a black colour depending on the direction of electric field lines flowing through it. If only a source-drain voltage V_{SD} is applied, nothing happens, because at the voltage levels typically used for MEM-FET applications (in the order of few volts at the most) the electric field of a source or drain electrode that is only coupled to a voltage source is not sufficient for setting the colour of the electrophoretic material. To the contrary, if a gate voltage V_{G} is applied simultaneously with a source-drain voltage V_{SD}, the MEM-FET is set to conductive state, an electric current flows through the channel region 113, and the resulting distribution of surface charge on the surfaces of the appropriate electrode (drain electrode 112 in the case of FIG. 6) causes a sufficiently strong electric field. Whether the layer of electrophoretic material 601 turns black or white in the eyes of someone looking from top down in the geometry of FIG. 6, depends on the polarity of the source-drain voltage V_{SD}: one polarity causes the layer of electrophoretic material 601 turn black, while the other polarity causes it to turn white.

Due to a known bistability characteristic of typical electrophoretic display materials it is not necessary to keep the voltages constantly applied. Brief, suitably timed voltage pulses in the gate and source-drain voltages are enough to set the colour of the electrophoretic display unit, which stays the same until it is changed with the next voltage pulses.

FIG. 7 illustrates an exemplary way of composing a display with a number of picture elements or pixels from the basic display units described in FIG. 6. Here we assume that the membrane 101 is transparent. Hatching in FIG. 7 does not illustrate cross sections but is only used to make it easier to graphically differentiate between various parts of the display. Gate electrodes 114 of a number of MEM-FETs located in (here: horizontal) rows appear as (horizontal) electrode strips that are visible through the transparent membrane 101 on its lower surface. The gate electrode strips could be designated as the bit lines or address lines. A semiconductor layer 113 on the top surface of the membrane constitutes the channel region of all MEM-FETs. On top of the semiconductor layer 113 there are source electrodes 111 and drain electrodes 112. Source electrodes 111 of a number of MEM-FETs located in (here: vertical) columns are connected together by (vertical) conductor strips 701, which could be called the data lines of the display structure. Similar conductor strips could be used to connect the drain electrodes 112 of suitably located (here: vertical) MEM-FETs together; alternatively each drain electrode 112 can be fixedly coupled to a local constant potential, for example the ground potential represented by a transparent ground plane (not shown) on a surface of the membrane 101. The idea of using gate electrode strips as bit or address lines and source- (or drain-) electrode-connecting data lines is to enable addressing each pixel in the display individually: coupling a voltage pulse to a particular address line and simultaneously to a particular data line will cause an electrophoretic effect in the pixel located at the crossing of the selected lines.

The electrophoretic material is deposited as layers 601, which (like many other layers of the structure: see e.g. the semiconductor layer 113) may, but does not have to, continue as a continuous layer across a number of adjacent MEM-FETs. At the location of each MEM-FET, the area 701 where the drain (or source) electrode 112 and the electrophoretic layer 601 overlap constitutes a pixel 702. The six pixels of the display in FIG. 7 are each illustrated with a horizontal hatch.

FIG. 8 illustrates schematically one possibility of providing each pixel of a MEM-FET-based display unit with an electrochemical power source 801 of its own. The power source 801 can be of the kind described above with reference to FIG. 2. It comprises an anode and a cathode, at least one of which is electrically coupled to the organic field-effect transistor 802 and/or a layer of electrophoretic material (not separately shown in FIG. 8) located adjacent to one of the electrodes in the MEM-FET. A membrane, which exhibits ion-conductivity in a section of the membrane that is located between said anode and said cathode, is provided as a basic support structure of the display unit.

Another further embodiment of the invention discloses a MEM-FET based memory device. The memory device of the further embodiment is manufactured on a proton conducting Nafion® 115 membrane. The organic semiconductor regioregular poly(3-hexylthiophene) (P3HT) is spin coated in inert atmosphere from a chloroform solution (4 mg/ml) on the membrane. The source and drain electrodes 30 nm thick gold is evaporated through a shadow mask. The used dimensions can be, for example 35 μm and 1.5 mm for channel length and width respectively. The gate electrode is made by drop casting poly(aniline) (PANI) from a toluene dispersion. The device shows typical MemFET behavior at low voltages before writing the memory. Advantageously by applying a +9 V bias for 30 seconds the ion conductivity of the membrane is dramatically decreased and the MemFET is no longer operating as a transistor. The on-current ratio before and after writing the device is roughly 30.

1-11. (canceled)

12. A circuit arrangement, comprising:
a first electronic component, which is an organic field-effect transistor and comprises a source electrode (111), a drain electrode (112), a channel region (113) and a gate electrode (114),
a second electronic component, which is electrically coupled to said first electronic component, and
a membrane (101) that is capable of constituting a mechanical support of the organic field-effect transistor;
characterized in that:
the membrane exhibits ion-conductivity between the channel region (113) and the gate electrode (114) and
the membrane exhibits ion-conductivity in a section (121, 403) of the membrane that is located between a first part of the second electronic component and a second part of the second electronic component.

13. A circuit arrangement according to claim 12, characterized in that said second part of the second electronic component is located on a different side of the membrane (101) than said first part, and the membrane exhibits ion-conductivity in a section (121) of the membrane that extends transversally across the membrane through at least a part of the thickness of the membrane between said first and second parts of the second electronic component.

14. A circuit arrangement according to claim 12, characterized in that said second part of the second electronic component is located on the same side of the membrane (101) as said first part, and the membrane exhibits ion-conductivity in a section (403) of the membrane that extends longitudinally along the membrane through at least a part of the distance between said first and second parts of the second electronic component.

15. A circuit arrangement according to claim 12, characterized in that
the second electronic component is an electrochemical power source and comprises an anode (202) and a cathode (203), and
the membrane exhibits ion-conductivity in a section (121) of the membrane that is located between said anode (202) and said cathode (203).

16. A circuit arrangement according to claim 15, characterized in that the second electronic component is a zinc-air battery, in which said anode (202) comprises a layer of zinc.

17. A circuit arrangement according to claim 12, characterized in that the second electronic component is an organic field-effect transistor, at least one part of which has been made non-functional, in order to make the second electronic component a memory cell with a fixed value.

18. A circuit arrangement according to claim 17, characterized in that said non-functionality of at least one part of the second electronic component is due to at least one of the following: over-oxidization of a gate electrode (334′), over-oxidization of a channel region (333′), over-oxidization of source electrode (331′), over-oxidization of drain electrode (332′).

19. A circuit arrangement according to claim 12, characterized in that
the circuit arrangement comprises a third electronic component, which is a non-functional organic field effect transistor and comprises a source electrode (331), a drain electrode (332), a channel region (333), and a gate electrode (334),
ion-conductivity in a section (335′) of the membrane that is located between the channel region (333) of the third electronic component and the gate electrode (334) of the third electronic component is lower than the ion-conductivity that the membrane exhibits between the channel region (313) and the gate electrode (314) of the first electronic component, in order to make the third electronic component a memory cell with a fixed value.

20. A circuit arrangement according to claim 12, characterized in that:
the second electronic component is an electrochromic display unit,
said first part is a first electrode (401) of said electrochromic display unit,
said second part is a second electrode (402) of said electrochromic display unit, and
at least one of said first (401) and second (402) electrodes comprises a redox-active polymer layer.

21. A display unit, comprising:
a first electronic component, which is an organic field-effect transistor and comprises a source electrode (111), a drain electrode (112), a channel region (113) and a gate electrode (114),
a membrane (101), which exhibits ion-conductivity between the channel region (113) and the gate electrode (114) and which is capable of constituting a mechanical support of the organic field-effect transistor, and
a layer of electrophoretic material (601) located adjacent to at least one of said source electrode (111) and said drain electrode (112).

22. A display unit according to claim 21, characterized in that:
the display unit comprises an electrochemical power source (801), which comprises an anode and a cathode, at least one of which is electrically coupled to at least one of said organic field-effect transistor (802) and said layer of electrophoretic material, and
the membrane exhibits ion-conductivity in a section of the membrane that is located between said anode and said cathode.

23. A circuit arrangement according to claim 13, characterized in that
the second electronic component is an electrochemical power source and comprises an anode (202) and a cathode (203), and
the membrane exhibits ion-conductivity in a section (121) of the membrane that is located between said anode (202) and said cathode (203).

24. A circuit arrangement according to claim 13, characterized in that the second electronic component is an organic field-effect transistor, at least one part of which has been made non-functional, in order to make the second electronic component a memory cell with a fixed value.

25. A circuit arrangement according to claim 13, characterized in that
the circuit arrangement comprises a third electronic component, which is a non-functional organic field effect transistor and comprises a source electrode (331), a drain electrode (332), a channel region (333), and a gate electrode (334),
ion-conductivity in a section (335′) of the membrane that is located between the channel region (333) of the third electronic component and the gate electrode (334) of the third electronic component is lower than the ion-conductivity that the membrane exhibits between the channel region (313) and the gate electrode (314) of the first electronic component, in order to make the third electronic component a memory cell with a fixed value.

26. A circuit arrangement according to claim 13, characterized in that:
the second electronic component is an electrochromic display unit,
said first part is a first electrode (401) of said electrochromic display unit,
said second part is a second electrode (402) of said electrochromic display unit, and
at least one of said first (401) and second (402) electrodes comprises a redox-active polymer layer.

27. A circuit arrangement according to claim 14, characterized in that
the second electronic component is an electrochemical power source and comprises an anode (202) and a cathode (203), and
the membrane exhibits ion-conductivity in a section (121) of the membrane that is located between said anode (202) and said cathode (203).

28. A circuit arrangement according to claim 14, characterized in that the second electronic component is an organic field-effect transistor, at least one part of which has been made non-functional, in order to make the second electronic component a memory cell with a fixed value.

29. A circuit arrangement according to claim 14, characterized in that
the circuit arrangement comprises a third electronic component, which is a non-functional organic field effect transistor and comprises a source electrode (331), a drain electrode (332), a channel region (333), and a gate electrode (334),
ion-conductivity in a section (335′) of the membrane that is located between the channel region (333) of the third electronic component and the gate electrode (334) of the third electronic component is lower than the ion-conductivity that the membrane exhibits between the channel region (313) and the gate electrode (314) of the first electronic component, in order to make the third electronic component a memory cell with a fixed value.

30. A circuit arrangement according to claim 14, characterized in that:
the second electronic component is an electrochromic display unit,
said first part is a first electrode (401) of said electrochromic display unit,
said second part is a second electrode (402) of said electrochromic display unit, and
at least one of said first (401) and second (402) electrodes comprises a redox-active polymer layer.
